(19) United States
(12) Patent Application Publication
(10) Pub. No.: US 2026/0113975 A1
(43) Pub. Date: Apr. 23, 2026

(54) LATERALLY DIFFUSED METAL OXIDE SEMICONDUCTOR DEVICE AND MANUFACTURING METHOD THEREFOR

(71) Applicants: SOUTHEAST UNIVERSITY, Nanjing (CN); CSMC TECHNOLOGIES FAB2 CO., LTD., Wuxi (CN)

(72) Inventors: Weifeng SUN, Wuxi (CN); Long ZHANG, Wuxi (CN); Sen ZHANG, Wuxi (CN); Siyang LIU, Wuxi (CN); Nailong HE, Wuxi (CN); Chengwu PAN, Wuxi (CN); Lihui GU, Wuxi (CN); Haoyu LI, Wuxi (CN); Shixiong CHONG, Wuxi (CN); Min ZOU, Wuxi (CN)

(21) Appl. No.: 18/996,057

(22) PCT Filed: May 11, 2024
(86) PCT No.: PCT/CN2024/092609

§ 371 Date: Jan. 17, 2025

(30) Foreign Application Priority Data
Nov. 7, 2023 (CN) 202311473834.X

(51) Int. Cl. H10D 30/65; H10D 30/01; H10D 62/10; H10D 62/60; H10D 64/27

(52) U.S. Cl. CPC H10D 30/65; H10D 30/0281; H10D 62/102; H10D 62/115; H10D 62/126; H10D 62/60; H10D 64/518

(57) ABSTRACT

In one aspect, a laterally diffused metal oxide semiconductor (LDMOS) device includes at least one cell structure. The cell structure includes: a substrate; a N-type first well region disposed in the substrate; the first well region being provided with a first region, an isolation region, and a second region that are sequentially arranged in a first direction; a P-type first doped region and a P-type second doped region, the first doped region being located in the first region, and the second doped region being located in the second region; and a P-type source region and a P-type drain region disposed in the substrate and located on two sides of the first doped region in a second direction. The first direction is a width direction of a conductive channel. The second direction is a length direction of the conductive channel.

### CROSS-REFERENCE TO RELATED APPLICATIONS

This application claims priority to Chinese Patent Application No. 202311473834X, entitled “LATERALLY DIFFUSED METAL OXIDE SEMICONDUCTOR DEVICE AND MANUFACTURING METHOD THEREFOR” and filed on Nov. 7, 2023, the content of which is incorporated herein by reference in its entireties.

### TECHNICAL FIELD

The present disclosure relates to the field of integrated circuit technologies, and in particular, to a laterally diffused metal oxide semiconductor (LDMOS) device and a manufacturing method therefor.

### BACKGROUND

With constant development of semiconductor technologies, the application of lateral double-diffuse metal oxide semiconductor (lateral double-diffuse MOS, LDMOS) devices has become increasingly widespread.

As an indispensable and important element in a high-voltage and low-voltage compatible process, a P-channel LDMOS plays an important role in high-voltage and low-voltage level conversion. In a kilovolt-level P-channel LDMOS, in order to achieve a maximum off-state breakdown voltage, a charge amount in a drift region and a charge amount in a substrate should reach charge balance. However, when the device is in an on state, excess holes injected into the drift region seriously break the charge balance. At a high voltage, an output current increases rapidly as an applied voltage increases, causing an on-state breakdown voltage of the device to be much lower than the off-state breakdown voltage, thereby reducing reliability of the device.

### SUMMARY

Accordingly, it is necessary to provide a laterally diffused metal oxide semiconductor (LDMOS) device and a manufacturing method therefor with respect to the above problem.

In order to achieve the above object, in a first aspect, the present disclosure provides a LDMOS device, including at least one cell structure, the cell structure including:
a substrate;
a N-type first well region disposed in the substrate; the first well region being provided with a first region, an isolation region, and a second region that are sequentially arranged in a first direction;
a P-type first doped region and a P-type second doped region, the first doped region being located in the first region, and the second doped region being located in the second region; and
a P-type source region and a P-type drain region disposed in the substrate; the source region being located on a side of the first doped region in a second direction, and the drain region being located on another side of the first doped region in the second direction; the first direction being a width direction of a conductive channel, and the second direction being a length direction of the conductive channel.

In an embodiment, a dimension of the source region in the first direction is equal to a dimension of the first doped region in the first direction. A dimension of the drain region in the first direction is equal to a dimension of the first well region in the first direction.

In an embodiment, a ratio of the dimension of the source region in the first direction to the dimension of the first well region in the first direction ranges from 0.3 to 0.5.

In an embodiment, the first region includes a first sub-region and a second sub-region that are arranged in the second direction. The second sub-region is located between the first sub-region and the source region.

Doping concentration of N-type impurities in the first sub-region is less than doping concentration of N-type impurities in the second sub-region.

Doping concentration of P-type impurities in the first sub-region is greater than doping concentration of P-type impurities in the second sub-region.

In an embodiment, a dimension of the first sub-region in the second direction is greater than a dimension of the second sub-region in the second direction.

In an embodiment, a ratio of a dimension of the first sub-region in the second direction to a dimension of the first region in the second direction ranges from 0.6 to 0.8.

In an embodiment, a boundary on a side of the first doped region in the first sub-region away from a surface of the substrate is a non-planar surface.

In an embodiment, the second region includes a third sub-region and a fourth sub-region that are arranged in the second direction. The third sub-region is located between the drain region and the fourth sub-region.

Doping concentration of N-type impurities in the third sub-region is less than doping concentration of N-type impurities in the fourth sub-region.

Doping concentration of P-type impurities in the third sub-region is greater than doping concentration of P-type impurities in the fourth sub-region.

In an embodiment, a dimension of the third sub-region in the second direction is less than a dimension of the fourth sub-region in the second direction.

In an embodiment, a ratio of a dimension of the third sub-region in the second direction to a dimension of the second region in the second direction ranges from 0.2 to 0.4.

In an embodiment, a boundary on a side of the second doped region in the third sub-region away from a surface of the substrate is a non-planar surface.

In an embodiment, the cell structure further includes:
an N-type body region and a P-type second well region respectively disposed in the substrate and located on two sides of the first doped region in the second direction; the source region being located in the body region, and the drain region being located in the second well region;
an N-type body lead-out region disposed in the body region; and
a gate disposed on the substrate and covering part of the body region.

In an embodiment, the LDMOS device includes a plurality of cell structures sequentially that are arranged in the first direction.

In two adjacent cell structures, first regions of the two cell structures are adjacent to each other, or second regions of the two cell structures are adjacent to each other.

In an embodiment, drain regions of the plurality of cell structures are sequentially connected to form an integrated drain region.

Source regions of the two adjacent cell structures are connected to form an integrated source region. Gates of the two adjacent cell structures are connected to form an integrated gate.

In an embodiment, the LDMOS device further includes a connection structure. The connection structure electrically connects two adjacent integrated gates.

In a second aspect, embodiments of the present disclosure provide a manufacturing method for a LDMOS device, including:
providing a substrate;
forming a N-type first well region, a P-type first doped region, and a P-type second doped region in the substrate; the first well region being provided with a first region, an isolation region, and a second region that are sequentially arranged in a first direction, the first doped region being formed in the first region, and the second doped region being formed in the second region; and
forming a P-type source region in the substrate and on a side of the first doped region in a second direction; and forming a P-type drain region in the substrate and on another side of the first doped region in the second direction; the first direction being a width direction of a conductive channel, and the second direction being a length direction of the conductive channel.

In an embodiment, the substrate has an implanted zone and a non-implanted zone that are adjacent to each other. The implanted zone has a first zone, a second zone, and a third zone that are sequentially arranged in the first direction. The first zone has a first sub-zone and a second sub-zone that are arranged in the second direction. The third zone has a third sub-zone and a fourth sub-zone that are arranged in the second direction.

The step of forming the N-type first well region, the P-type first doped region, and the P-type second doped region in the substrate; the first well region being provided with the first region, the isolation region, and the second region that are sequentially arranged in the first direction, the first doped region being formed in the first region, and the second doped region being formed in the second region includes:
forming a first patterned mask layer on the substrate; the first patterned mask layer including a mask portion, a plurality of first mask strips, and a plurality of second mask strips, the mask portion covering the non-implanted zone, the plurality of first mask strips being spaced apart in the first sub-zone along the second direction, and the plurality of second mask strips being spaced apart in the third sub-zone along the second direction;
implanting N-type impurities into the substrate to form the first well region;
removing the first patterned mask layer; and
forming the first doped region and the second doped region in the substrate.

Details of one or more embodiments of the present disclosure are set forth in the following accompanying drawings and descriptions. Other features, objects, and advantages of the present disclosure become obvious from the detailed description, the accompanying drawings, and the claims.

### BRIEF DESCRIPTION OF THE DRAWINGS

In order to more clearly illustrate the technical solutions in embodiments of the present disclosure or the conventional art, the accompanying drawings used in the description of the embodiments or the conventional art will be briefly introduced below. It is apparent that, the accompanying drawings in the following description are only for some embodiments of the present disclosure, and other drawings can be obtained by those of ordinary skill in the art from the disclosed drawings without creative efforts.

FIG. 1 is a schematic view of a partial structure of a LDMOS device according to embodiments of the present disclosure.

FIG. 2 is a schematic top view of the device shown in FIG. 1.

FIG. 3 is a schematic sectional view of a structure of the device shown in FIG. 2 taken along a line A-A.

FIG. 4 is a schematic sectional view of a structure of the device shown in FIG. 2 taken along a line B-B.

FIG. 5 is a schematic sectional view of a structure of the device shown in FIG. 2 taken along a line C-C.

FIG. 6 is a schematic view of a partial structure of another LDMOS device according to embodiments of the present disclosure.

FIG. 7 is a schematic view of a partial structure of yet another LDMOS device according to embodiments of the present disclosure.

FIG. 8 shows output characteristic curves of a device in the related art and a device according to embodiments of the present disclosure.

FIG. 9 is a schematic flowchart of a manufacturing method for a LDMOS device according to embodiments of the present disclosure.

FIG. 10 is a schematic flowchart of S200 in the manufacturing method shown in FIG. 9.

FIG. 11A to FIG. 11D are schematic structural views of the device taken along a line A-A during the manufacturing method shown.

FIG. 12A to FIG. 12D are schematic structural views of the device taken along a line B-B during the manufacturing method shown.

FIG. 13A to FIG. 13D are schematic structural views of the device taken along a line B-B during the manufacturing method shown.

### ILLUSTRATION FOR REFERENCE SIGNS

1: LDMOS device: 10: cell structure; 11: substrate; 111: base layer; 1111: buried layer; 1112: deep well region; 112: epitaxial layer; 12: first well region; 121: first region; 1211: first sub-region; 1212: second sub-region; 122: isolation region; 123: second region; 1231: third sub-region; 1232: fourth sub-region; 131: first doped region; 132: second doped region; 141: source region; 142: drain region; 151: second well region; 152: body region; 153: body lead-out region; 16: gate; 161: connection structure; 17: field oxide layer; 18: dielectric layer; 191: first conductive structure; 192: second conductive structure; 201: first patterned mask layer; 2011: mask portion; 2012: first mask strip; 2013: second mask strip; 202: sacrificial oxide layer; 203: second patterned mask layer.

### DETAILED DESCRIPTION

The technical solutions in the embodiments of the present disclosure will be described clearly and completely below with reference to the accompanying drawings in the embodiments of the present disclosure. Apparently, the described embodiments are merely some of, rather than all of the embodiments of the present disclosure. All other embodiments acquired by those of ordinary skill in the art without creative efforts based on the embodiments of the present disclosure shall fall within the protection scope of the present disclosure.

Unless otherwise defined, all technical and scientific terms used herein shall have the same meanings as commonly understood by those skilled in the art to which the present disclosure belongs. The terms used in the specification of the present disclosure are intended to merely describe specific embodiments, rather than to limit the present disclosure.

It should be understood that when an element or layer is referred to as being “on”, “adjacent to”, “connected to”, or “coupled to” another element or layer, the element or layer may be directly on, adjacent to, connected to, or coupled to the another element or layer, or an intervening element or layer may be disposed therebetween. On the contrary, when an element is referred to as being “directly on”, “directly adjacent to”, “directly connected to”, or “directly coupled to” another element or layer, no intervening element or layer may be disposed therebetween. It should be understood that although terms such as first, second, and third may be used to describe various elements, components, regions, layers, doping types, and/or portions, the elements, components, regions, layers, doping types, and/or portions may not be limited to such terms. Such terms are used only to distinguish one element, component, region, layer, doping type, or portion from another element, component, region, layer, doping type, or portion. Thus, without departing from the teaching of the present disclosure, a first element, component, region, layer, doping type, or portion may be referred to as a second element, component, region, layer, doping type, or portion. For example, a first doping type may be referred to as a second doping type, and similarly, the second doping type may be referred to as the first doping type. The first doping type and the second doping type are different doping types. For example, the first doping type may be P-type and the second doping type may be N-type, or the first doping type may be N-type and the second doping type may be P-type.

Spatial relationship terms such as “under”, “underneath”, “below”, “beneath”, “over”, and “above” may be used for illustrative purposes to describe a relationship between one element or feature and another element or feature illustrated in the figures. It should be understood that, in addition to the orientations illustrated in the figures, the spatial relationship terms are intended to further include different orientations of the device in use and operation. For example, if the device in the figures is turned over, the element or feature described as “below”, “underneath” or “under” another element or feature may be oriented as “on” the another element or feature. Thus, the exemplary terms “below” and “under” may include two orientations of above and below. In addition, the device may include additional orientations (e.g., may be rotated 90-degree rotation or otherwise oriented), and thus spatial descriptors used herein may be interpreted accordingly.

In use, the singular forms of “a/an”, “one”, and “the” may also include plural forms, unless otherwise clearly specified in the context. It should be further understood that the terms “include/comprise” and/or “have” specify the presence of the features, integers, steps, operations, components, portions, and/or groups thereof, but may not exclude the presence or addition of one or more of other features, integers, steps, operations, components, portions, and/or groups thereof. At the same time, in the specification, the term “and/or” may include any and all combinations of associated listed items.

Embodiments of the present disclosure are described herein with reference to cross-sectional views of schematic views of ideal embodiments (and intermediate structures) of the present disclosure. Correspondingly, illustrated shape variations caused by, for example, manufacturing techniques and/or tolerances, may be expected. Thus, the embodiments of the present disclosure may not be limited to the specific shapes of the regions illustrated herein, but may include shape deviations caused by, for example, the manufacturing techniques. For example, an implanted zone illustrated as a rectangle, typically, has rounded or curved features and/or a gradient of implant concentration at its edges rather than a binary change from an implanted zone to a non-implanted zone. Likewise, a buried region formed by implantation may result in some implantation in the region between the buried region and a surface through which the implantation takes place. Thus, the regions shown in the drawings are generally illustrative, and their shapes are not intended to show the actual shapes of the regions of the device, and are not intended to limit the scope of the present disclosure.

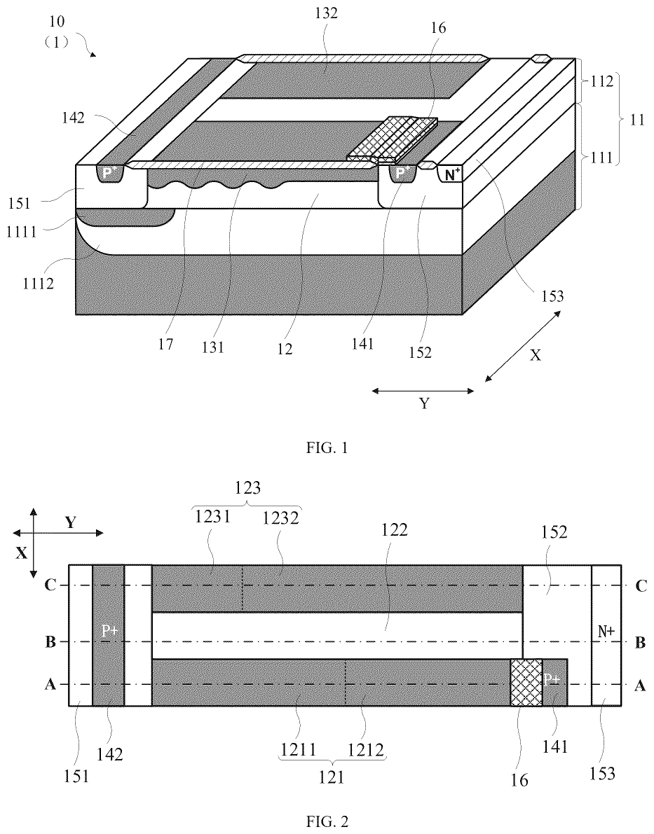

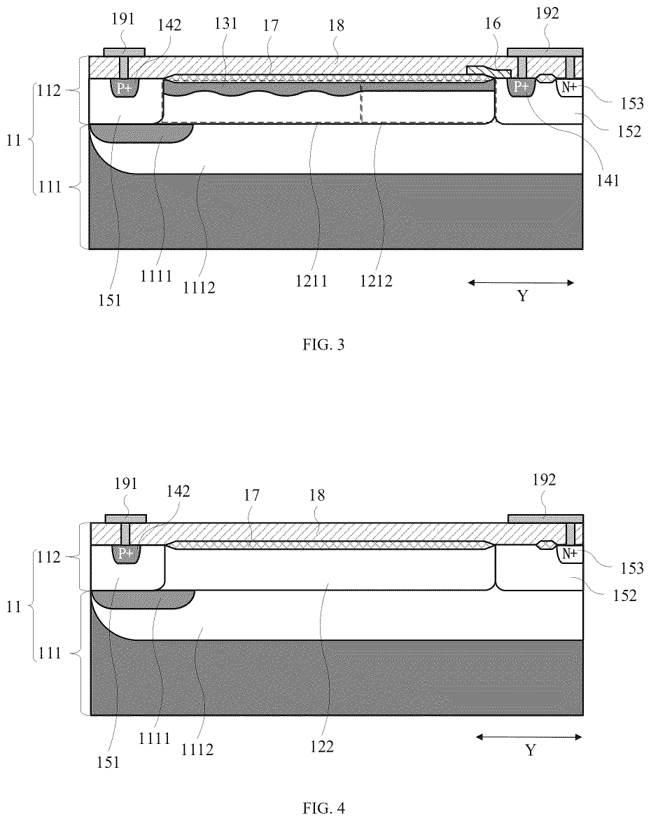

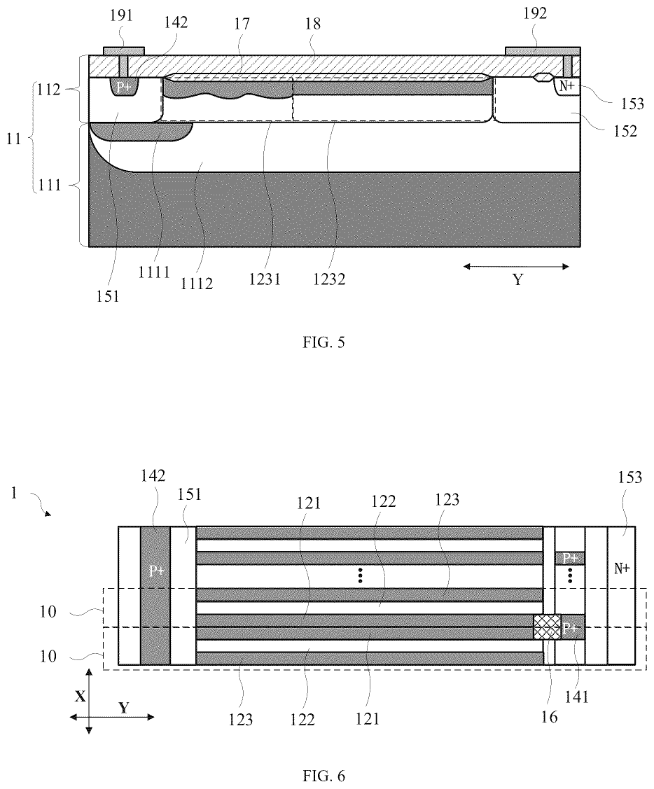

In a first aspect, referring to FIG. 1, FIG. 2, FIG. 3, FIG. 4, and FIG. 5, embodiments of the present disclosure provide a laterally diffused metal oxide semiconductor (LDMOS) device 1, including at least one cell structure 10. The cell structure 10 includes a substrate 11, a N-type first well region 12, a P-type first doped region 131, a P-type second doped region 132, a P-type source region 141, and a P-type drain region 142.

The first well region 12 is provided in the substrate 11. The first well region 12 is provided with a first region 121, an isolation region 122, and a second region 123 that are sequentially arranged in a first direction X. The first doped region 131 is located in the first region 121, and the second doped region 132 is located in the second region 123. Herein, the isolation region 122 has a side adjacent to the first region 121 and another side adjacent to the second region 123.

Further, the source region 141 and the drain region 142 are both located in the substrate 11. Moreover, the source region 141 is located on a side of the first doped region 131 in a second direction Y, and the drain region 142 is located on another side of the first doped region 131 in the second direction Y. The first direction X refers to the width direction of a conductive channel, and the second direction Y refers to the length direction of the conductive channel.

In the LDMOS device 1 according to the embodiments of the present disclosure, the first well region 12 is divided into the first region 121, the isolation region 122, and the second region 123 that are sequentially arranged in the width direction of the conductive channel; the first doped region 131 is disposed in the first region 121, and the second doped region 132 is disposed in the second region 123. In this way, the first doped region 131 is equivalent to a conductive region, and the second doped region 132 is equivalent to an auxiliary depletion region. When the device is in an on state, the drain region 142, the conductive region, and the source region 141 form a conductive path. The isolation region 122 can prevent current from flowing from the conductive region to the auxiliary depletion region, and a charge balance state of the auxiliary depletion region may not change. Compared with traditional devices, the width of the conductive region of the device according to the embodiments of the present disclosure is reduced, so that a proportion of the change in the charge balance state of the device after and before ON is reduced. Therefore, a rapid increase in the output current in the on state can be suppressed, thereby improving stability of the output current of the device, and improving reliability of the device.

In an embodiment, the substrate 11 includes a base layer 111 and an epitaxial layer 112 that are stacked. The base layer 111 and the epitaxial layer 112 are both of P-type. It is to be noted that the base layer 111 may be made of monocrystalline silicon, poly crystalline silicon, amorphous silicon, silicon germanium compound, silicon-on-insulator (SOI), or low-temperature poly-silicon (LTPS), or the like, or other materials known to those skilled in the art. The base layer 111 may provide a supporting foundation for a structural layer on the base layer 111.

In an embodiment, a dimension of the source region 141 in the first direction X is equal to a dimension of the first doped region 131 in the first direction X. A dimension of the drain region 142 in the first direction X is equal to a dimension of the first well region 12 in the first direction X.

In an example, the dimension of the source region 141 in the first direction X refers to the width of the source region 141; the dimension of the first doped region 131 in the first direction X refers to the width of the first doped region 131; the dimension of the drain region 142 in the first direction X refers to the width of the drain region 142; and the dimension of the first well region 12 in the first direction X refers to the width of the first well region 12.

In this way, by reducing the width of the source region 141, hole injection efficiency of the source region 141 at the same voltage can be reduced, which helps suppress a rapid increase in the output current in the on state, thereby improving the stability of the output current of the device and improving the reliability of the device.

In an embodiment, a ratio of the dimension of the source region 141 in the first direction X to the dimension of the first well region 12 in the first direction X ranges from 0.3 to 0.5. That is, a ratio of the dimension of the first doped region 131 (or the first region 121) in the first direction X to the dimension of the first well region 12 in the first direction X ranges from 0.3 to 0.5.

Exemplarily, the ratio of the dimension of the source region 141 in the first direction X to the dimension of the first well region 12 in the first direction X may be 0.3, 0.35, 0.4, 0.45, 0.48, or 0.5.

Through the above arrangement, an effective conductive channel width can account for 30% to 50% of the width of the entire cell structure 10. That is, compared with the traditional devices, the width of the conductive channel is reduced, which helps suppress a rapid increase in the output current in the on state, thereby improving the stability of the output current of the device and improving the reliability of the device.

It may be understood that a ratio of the sum of the dimensions of the isolation region 122 and the second doped region 132 (or the second region 123) in the first direction X to the dimension of the first well region 12 in the first direction X ranges from 0.5 to 0.7. That is, the ratio of the sum of the dimensions of the isolation region 122 and the second doped region 132 (or the second region 123) in the width direction of the conductive channel to the dimension of the first well region 12 in the width direction of the conductive channel ranges from 0.5 to 0.7.

In an embodiment, the dimension of the first well region 12 in one cell structure 10 in the width direction of the conductive channel is equal to the dimension of this cell structure 10 in the width direction of the conductive channel. Exemplarily, the dimension of the cell structure 10 in the width direction of the conductive channel refers to the width of the cell structure 10.

In an embodiment, referring to FIG. 2, the first region 121 includes a first sub-region 1211 and a second sub-region 1212 that are arranged in the second direction Y. The second sub-region 1212 is located between the first sub-region 1211 and the source region 141. The first sub-region 1211 is located between the drain region 142 and the second sub-region 1212. Doping concentration of N-type impurities in the first sub-region 1211 is less than doping concentration of N-type impurities in the second sub-region 1212. Doping concentration of P-type impurities in the first sub-region 1211 is greater than doping concentration of P-type impurities in the second sub-region 1212.

Through the above arrangement, doping concentration of P-type impurities in the first doped region 131 can be increased, which helps prevent premature breakdown of the device in the on state, thereby improving the reliability of the device.

In an embodiment, the dimension of the first sub-region 1211 in the second direction Y is greater than the dimension of the second sub-region 1212 in the second direction Y. In an example, the dimension of the first sub-region 1211 in the second direction Y refers to the length of the first sub-region 1211, and the dimension of the second sub-region 1212 in the second direction Y refers to the length of the second sub-region 1212.

Through the above arrangement, a proportion of the first sub-region 1211 in the first region 121 is larger, which helps further increase the doping concentration of the P-type impurities in the first sub-region 1211, thereby helping prevent premature breakdown of the device in the on state and improving the reliability of the device.

In an embodiment, a ratio of the dimension of the first sub-region 1211 in the second direction Y to the dimension of the first region 121 in the second direction Y ranges from 0.6 to 0.8. Exemplarily, the ratio of the dimension of the first sub-region 1211 in the second direction Y to the dimension of the first region 121 in the second direction Y may be 0.60, 0.65, 0.72, 0.76, or 0.8.

In an embodiment, a ratio of the dimension of the first sub-region 1211 in the length direction of the conductive channel to the dimension of the first doped region 131 in the length direction of the conductive channel ranges from 0.6 to 0.8.

Through the above arrangement, doping concentration of P-type impurities in the first region 121 can be within a reasonable range, which, on the one hand, can prevent premature breakdown of the device in the on state and help improve the reliability of the device, and on the other hand, can prevent degradation of performance of the device caused by excessively low doping concentration of the N-type impurities in the first region 121.

In an embodiment, referring to FIG. 3, a boundary on a side of the first doped region 131 in the first sub-region 1211 away from a surface of the substrate 11 is a non-planar surface. In an example, a bottom surface of the first doped region 131 in the first sub-region 1211 is a non-planar surface. Exemplarily, the non-planar surface may be a regular wavy surface, an irregular wavy surface, a zigzag surface, a crenellated surface, or the like.

It is to be noted that, in the embodiments of the present disclosure, N-type impurities are implanted into the first sub-region 1211 in a segmented manner, so that the doping concentration of the N-type impurities in the first sub-region 1211 is less than the doping concentration of the N-type impurities in the second sub-region 1212. Therefore, the doping concentration of the P-type impurities in the first sub-region 1211 is greater than the doping concentration of the P-type impurities in the second sub-region 1212. Further, the bottom surface of the first doped region 131 in the first sub-region 1211 is a non-planar surface by using a segmented implantation process. In addition, by using the segmented implantation process, the control over the output current of the device in the on state is achieved without introducing additional complex processes.

In an embodiment, referring to FIG. 2, the second region 123 includes a third sub-region 1231 and a fourth sub-region 1232 that are arranged in the second direction Y. The third sub-region 1231 is located between the drain region 142 and the fourth sub-region 1232. The fourth sub-region 1232 is located between the source region 141 and the third sub-region 1231. Doping concentration of N-type impurities in the third sub-region 1231 is less than doping concentration of N-type impurities in the fourth sub-region 1232. Doping concentration of P-type impurities in the third sub-region 1231 is greater than doping concentration of P-type impurities in the fourth sub-region 1232.

Through the above arrangement, doping concentration of P-type impurities in the second doped region 132 can be increased, which helps prevent premature breakdown of the device in the on state, thereby improving the reliability of the device.

In an embodiment, the dimension of the third sub-region 1231 in the second direction Y is less than the dimension of the fourth sub-region 1232 in the second direction Y. In an example, the dimension of the third sub-region 1231 in the second direction Y refers to the length of the third sub-region 1231, and the dimension of the fourth sub-region 1232 in the second direction Y refers to the length of the fourth sub-region 1232.

Through the above arrangement, a proportion of the third sub-region 1231 in the second region 123 is larger, so that N-type doping concentration of the second region 123 is greater than N-type doping concentration of the first region 121. In the on state, holes are injected into the first region 121, and an area of the depletion region in the first doped region 131 is reduced. Therefore, the concentration of N-type impurities in the second region 123 can be increased so that depletion of the first doped region 131 can be assisted, a degree of damage to the charge balance of the first region 121 can be reduced, and a rapid increase in the output current in the on-state can be suppressed, thereby improving the stability of the output current of the device, and improving the reliability of the device.

In an embodiment, a ratio of the dimension of the third sub-region 1231 in the second direction Y to the dimension of the second region 123 in the second direction Y ranges from 0.2 to 0.4. Exemplarily, the ratio of the dimension of the third sub-region 1231 in the second direction Y to the dimension of the second region 123 in the second direction Y may be 0.2, 0.25, 0.29, 0.32, 0.35, 0.38, or 0.4.

In an embodiment, a ratio of the dimension of the third sub-region 1231 in the length direction of the conductive channel to the dimension of the second doped region 132 in the length direction of the conductive channel ranges from 0.2 to 0.4.

Through the above arrangement, the doping concentration of P-type impurities in the second doped region 132 can be within a reasonable range, which, on the one hand, can assist the depletion of the first doped region 131 and reduce the degree of damage to the charge balance of the first region 121, and on the other hand, can prevent the degradation of performance of the device caused by excessively low doping concentration of the N-type impurities in the second region 12.

In an embodiment, referring to FIG. 5, a boundary on a side of the second doped region 132 in the third sub-region 1231 away from the surface of the substrate 11 is a non-planar surface. In an example, a bottom surface of the first doped region 131 in the third sub-region 1231 is a non-planar surface. Exemplarily, the non-planar surface may be a regular wavy surface, an irregular wavy surface, a zigzag surface, a crenellated surface, or the like.

It is to be noted that, in the embodiments of the present disclosure, N-type impurities are implanted into the third sub-region 1231 in a segmented manner, so that the doping concentration of the N-type impurities in the third sub-region 1231 is less than the doping concentration of the N-type impurities in the fourth sub-region 1232. Therefore, the doping concentration of the P-type impurities in the third sub-region 1231 is greater than the doping concentration of the P-type impurities in the fourth sub-region 1232. Further, the bottom surface of the first doped region 131 in the third sub-region 1231 is a non-planar surface by using a segmented implantation process. In addition, by using the segmented implantation process, the control over the output current of the device in the on state is achieved without introducing additional complex processes.

In an embodiment, referring to FIG. 1, FIG. 2, FIG. 3, FIG. 4, and FIG. 5, the cell structure 10 further includes an N-type body region 152, a P-type body lead-out region 153, a P-type second well region 151, and a gate 16. The body region 152 and the second well region 151 are respectively disposed in the substrate 11 and located on two sides of the first doped region 131 in the second direction Y. The source region 141 and the body lead-out region 153 are located in the body region 152, and the drain region 142 is located in the second well region 151. The gate 16 is disposed on the substrate 11 and covers part of the body region 152. A region covered by the gate 16 is a conductive channel. Further, an N-type deep well region 1112 and a P-type buried layer 1111 are disposed in the base layer 111.

In an example, the dimension of the gate 16 in the first direction X is equal to the dimension of the source region 141 in the first direction X. In an example, the width of the gate 16 is equal to the width of the source region 141. In this way, a ratio of the width of the gate 16 to the width of the cell structure 10 may be equal to a ratio of the width of the first doped region 131 to the width of the cell structure 10, so that the width of the conductive channel can be reduced, which helps suppress a rapid increase in the output current in the on state, thereby improving the stability of the output current of the device and improving the reliability of the device.

In an embodiment, referring to FIG. 6, the LDMOS device 1 includes a plurality of cell structures 10 that are sequentially arranged in the first direction X. In two adjacent cell structures 10, first regions 121 of the two cell structures 10 are adjacent to each other, or second regions 123 of the two cell structures 10 are adjacent to each other.

In an example, taking the orientation in FIG. 6 as an example, from bottom to top, the first region 121 of the first cell structure 10 is adjacent to the first region 121 of the second cell structure 10; the second region 123 of the second cell structure 10 is adjacent to the second region 123 of the third cell structure 10; the first region 121 of the third cell structure 10 is adjacent to the first region 121 of the fourth cell structure 10, . . . and so on.

Through the above arrangement, it is conducive to increasing arrangement density of the cell structure 10 per unit area of the device, thereby improving performance of the device.

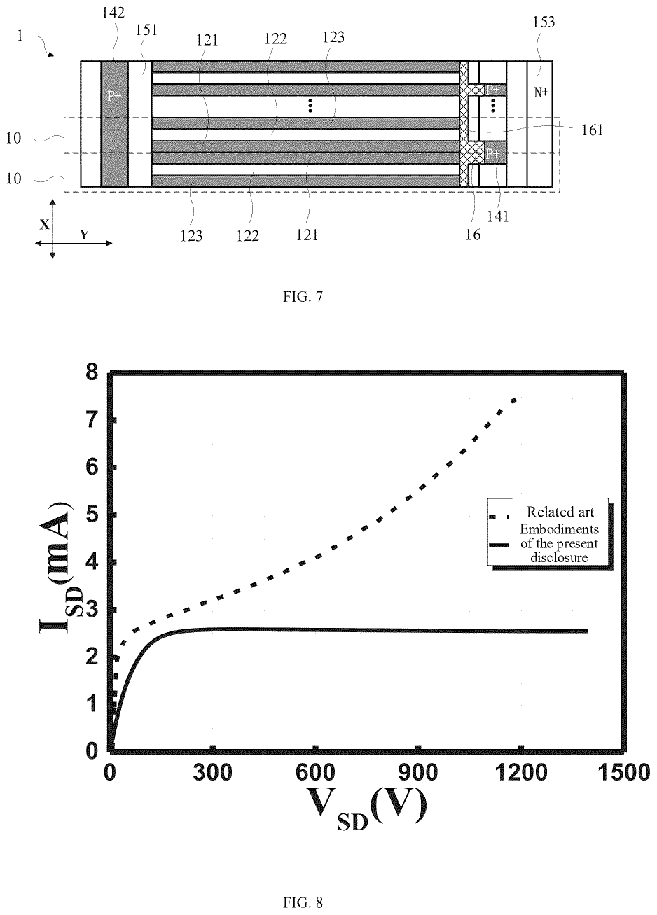

In an embodiment, referring to FIG. 7, drain regions 142 of the plurality of cell structures 10 are sequentially connected to form an integrated drain region 142. Source regions 141 of two adjacent cell structures 10 are connected to form an integrated source region 141, and gates 16 of the two adjacent cell structures 10 are connected to form an integrated gate 16.

Through the above arrangement, it is conducive to increasing arrangement density of the cell structure 10 per unit area of the device, thereby improving performance of the device.

In an embodiment, the LDMOS device 1 further includes a connection structure 161. The connection structure 161 electrically connects two adjacent integrated gates 16.

In an embodiment, referring to FIG. 1 and FIG. 3, the LDMOS device 1 further includes a field oxide layer 17, a dielectric layer 18, a first conductive structure 191, and a second conductive structure 192. The field oxide layer 17 covers at least the first well region 12. The dielectric layer 18 covers the field oxide layer 17, the gate 16, and an exposed surface of the substrate 11. The first conductive structure 191 extends through the dielectric layer 18 and is electrically connected to the drain region 142. The second conductive structure 192 extends through the dielectric layer 18 and is electrically connected to the source region 141. Further, the second conductive structure 192 is further electrically connected to the body lead-out region 153. In an example, the first conductive structure 191 is a drain electrode, and the second conductive structure 192 is a source electrode.

Referring to FIG. 8, performances of the device in the related art and the device in the embodiments of the present disclosure was tested by the applicant. As can be seen from the figures, the device in the embodiments of the present disclosure can better suppress upwarping of an output characteristic curve at a high voltage, thereby improving the stability of the output current.

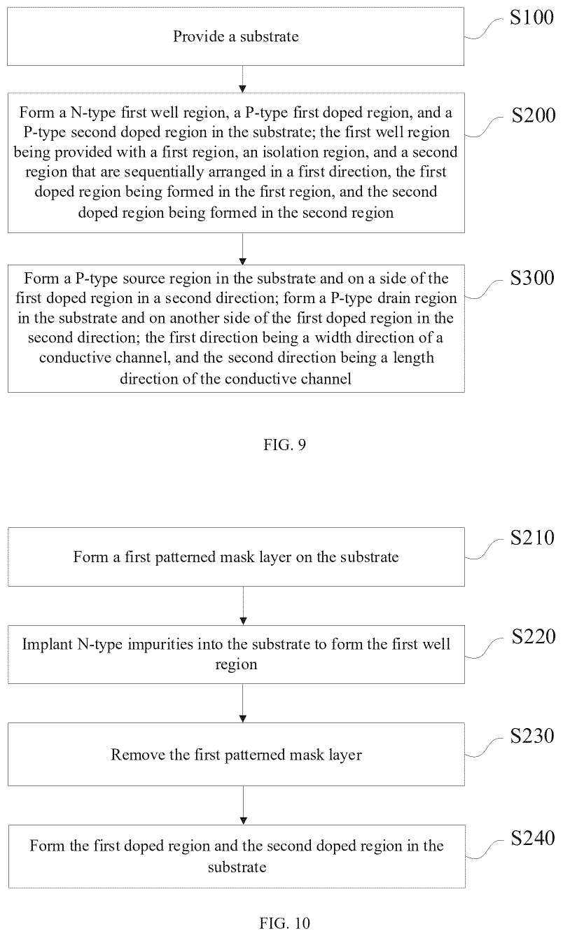

In a second aspect, referring to FIG. 9, embodiments of the present disclosure provide a manufacturing method for a LDMOS device, specifically including the following steps.

At S100, a substrate 11 is provided. Exemplarily, the substrate 11 includes a base layer 111 and an epitaxial layer 112 that are stacked. The base layer 111 and the epitaxial layer 112 are both of P-type.

At S200, a N-type first well region 12, a P-type first doped region 131, and a P-type second doped region 132 are formed in the substrate 11. The first well region 12 is provided with a first region 121, an isolation region 122, and a second region 123 that are sequentially arranged in a first direction X. The first doped region 121 is formed in the first region 131. The second doped region 123 is formed in the second region 132.

At S300, a P-type source region 141 is formed in the substrate 11 and on a side of the first doped region 131 in a second direction Y; and a P-type drain region 142 is formed in the substrate 11 and on another side of the first doped region 131 in the second direction. The first direction X is a width direction of a conductive channel, and the second direction Y is a length direction of the conductive channel.

In the manufacturing method for a LDMOS device according to the embodiments of the present disclosure, the first well region 12 is divided into the first region 121, the isolation region 122, and the second region 123 that are sequentially arranged in the width direction of the conductive channel; the first doped region 131 is disposed in the first region 121; and the second doped region 132 is disposed in the second region 123. In this way, the first doped region 131 is equivalent to a conductive region, and the second doped region 132 is equivalent to an auxiliary depletion region. When the device is in an on state, the drain region 142, the conductive region, and the source region 141 form a conductive path. The isolation region 122 can prevent current from flowing from the conductive region to the auxiliary depletion region, and a charge balance state of the auxiliary depletion region may not change. Compared with traditional devices, the width of the conductive region of the device according to the embodiments of the present disclosure is reduced, so that a proportion of the change in the charge balance state of the device after and before ON is reduced. Therefore, a rapid increase in the output current in the on state can be suppressed, thereby improving stability of the output current of the device, and improving reliability of the device.

In an embodiment, the substrate 11 has an implanted zone (not shown) and a non-implanted zone (not shown) adjacent to each other. The implanted zone has a first zone (not shown), a second zone (not shown), and a third zone (not shown) that are sequentially arranged in the first direction X. The first zone has a first sub-zone (not shown) and a second sub-zone (not shown) that are arranged in the second direction Y. The third zone has a third sub-zone (not shown) and a fourth sub-zone (not shown) that are arranged in the second direction Y.

Herein, it is to be noted that the implanted zone refers to a zone on the substrate 11 where the first well region 12 is required to be formed, and the non-implanted zone refers to a zone on the substrate 11 where the first well region 12 is not formed. The first zone is a zone on the substrate 11 corresponding to the first region 121. The second zone is a zone on the substrate 11 corresponding to the isolation region 122. The third zone is a zone on the substrate 11 corresponding to the second region 123. The first sub-zone is a zone on the substrate 11 corresponding to the first sub-region 1211. The second sub-zone is a zone on the substrate 11 corresponding to the second sub-region 1212. The third sub-zone is a zone on the substrate 11 corresponding to the third sub-region 1231. The fourth sub-zone is a zone on the substrate 11 corresponding to the fourth sub-region 1232.

In an example, S200 specifically includes the following steps.

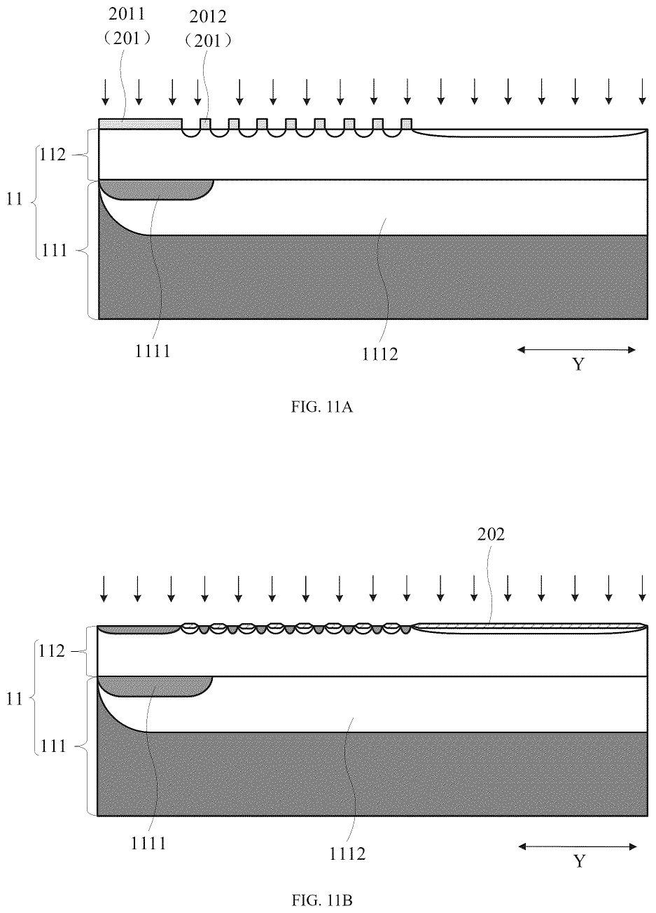

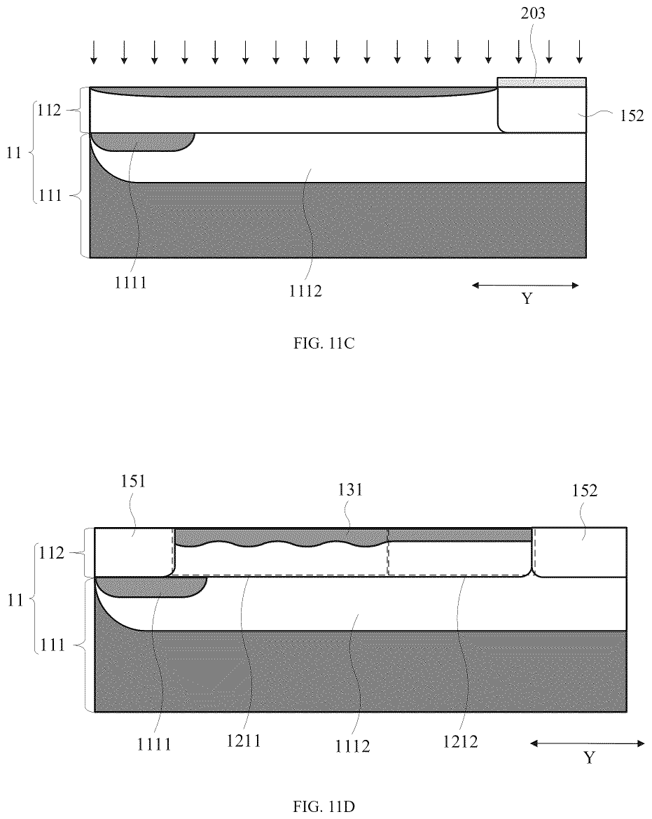

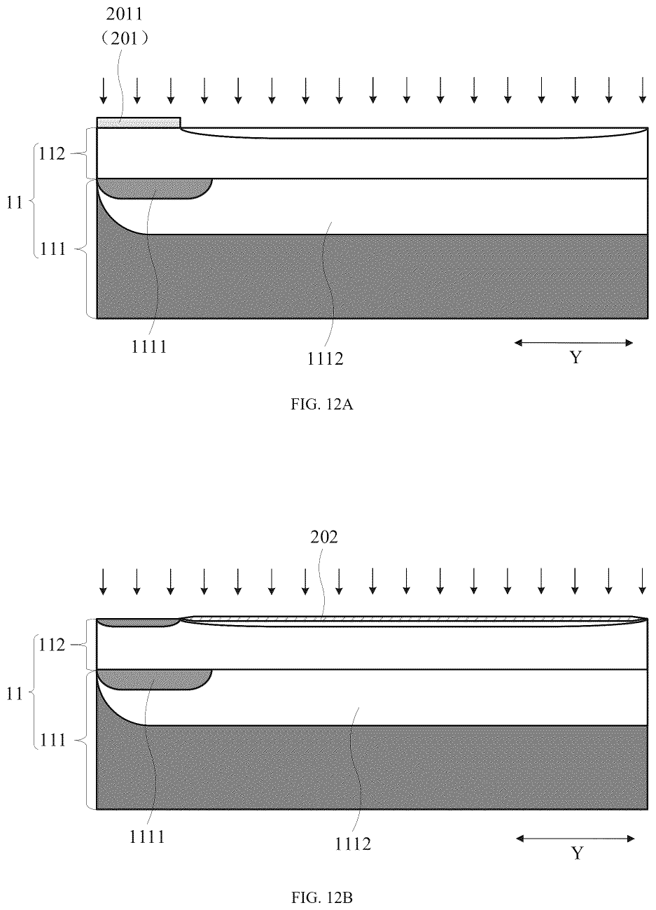

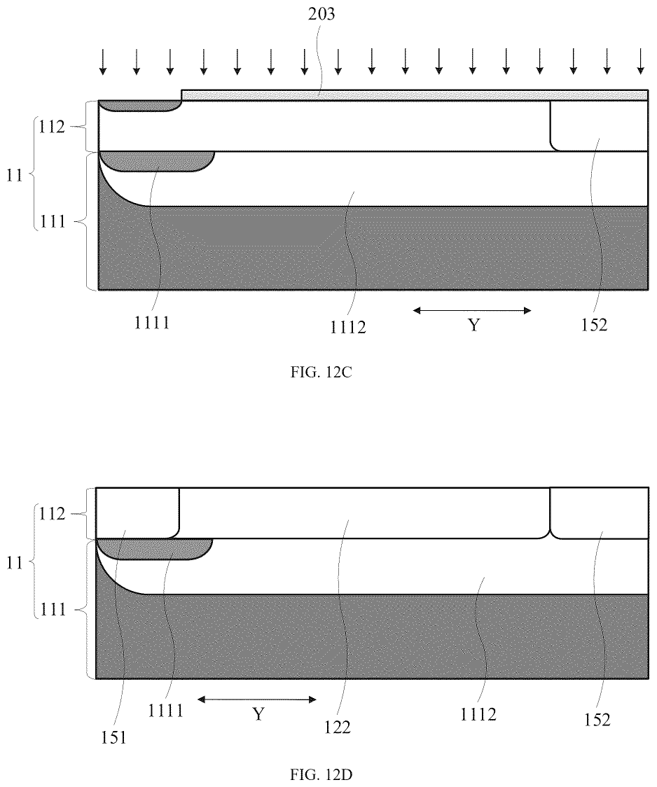

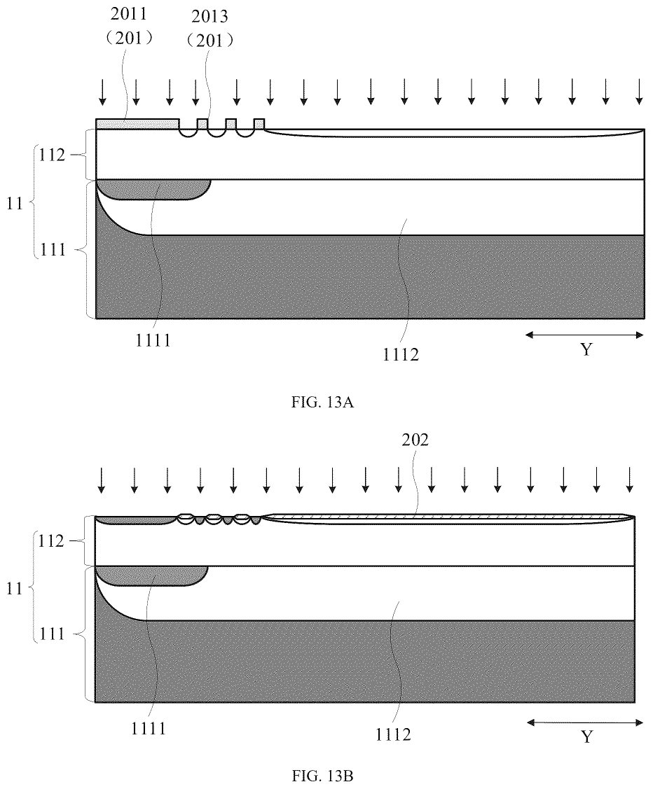

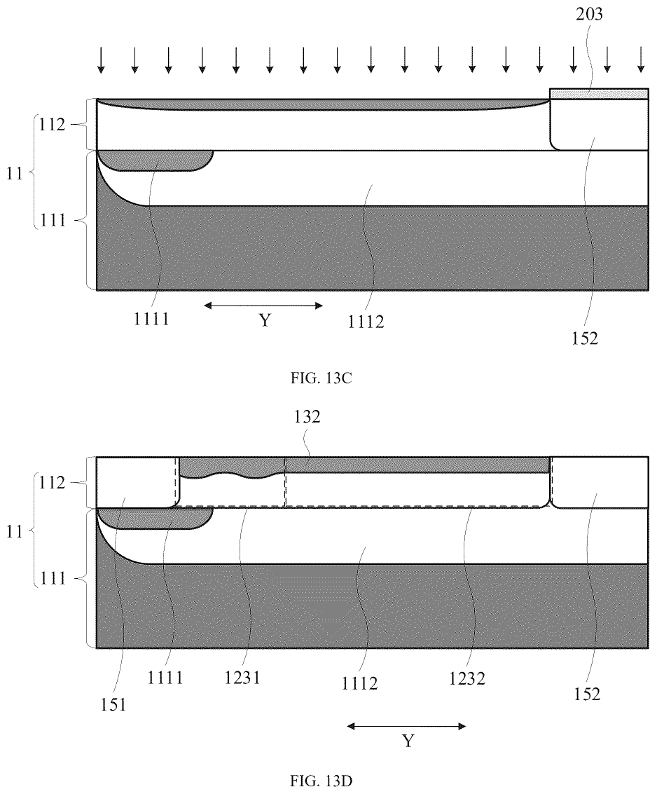

At S210, a first patterned mask layer 201 is formed on the substrate 11. A structure formed by the first patterned mask layer 201 is shown in FIG. 11A, FIG. 12A, and FIG. 13A. The first patterned mask layer 201 includes a mask portion 2011, a plurality of first mask strips 2012, and a plurality of second mask strips 2013. The mask portion 2011 covers the non-implanted zone. The plurality of first mask strips 2012 are spaced apart in the first sub-zone along the second direction Y. The plurality of second mask strips 2013 are spaced apart in the third sub-zone along the second direction Y. Exemplarily, the first patterned mask layer 201 is photoresist.

In this way, the first sub-zone and the third sub-zone are covered in a segmented manner, which can facilitate segmented implantation of the first sub-zone and the third sub-zone in the subsequent processes.

At S220, N-type impurities are implanted into the substrate 11 to form the first well region 12. Exemplarily, the N-type impurities are implanted by using an ion implantation process.

Specifically, referring to FIG. 11A, part of the first sub-zone is covered by the first mask strip 2012. Therefore, no N-type impurities is implanted into the region covered by the first mask strip 2012, so that the doping concentration of the N-type impurities in the first sub-zone is less than the doping concentration of N-type impurities in the second sub-zone, and then the doping concentration of P-type impurities in the first sub-zone is greater than the doping concentration of P-type impurities in the second sub-zone. The third sub-zone is disposed as same as the first sub-zone. Details are not repeatedly described herein again.

At S230, the first patterned mask layer 201 is removed. A structure formed by the first patterned mask layer 201 is shown in FIG. 11B, FIG. 12B, and FIG. 13B. In an example, after the first patterned mask layer 201 is removed, a sacrificial oxide layer 202 is formed on a surface of the substrate 11.

At S240, the first doped region 131 and the second doped region 132 are formed in the substrate 11.

In an embodiment, referring to FIG. 11B, FIG. 11C, FIG. 12B, FIG. 12C, FIG. 13B, and FIG. 13C, S240 specifically includes the following steps.

At S241, P-type impurities are implanted into the substrate 11 for the first time.

At S242, the sacrificial oxide layer 202 is removed.

At S243, N-type impurities are implanted into the substrate 11 to form a body region 152.

At S244, a second patterned mask layer 203 is formed on the substrate 11.

At S245, the P-type impurities are implanted into the substrate 11 for the second time.

At S246, the substrate 11 is annealed.

It is to be noted that due to that ion implantation may damage the substrate 11, mobility and lifetime of electron-hole pairs may be greatly reduced. In addition, most of the implanted ions are not positioned at lattice positions in the form of substitution. In order to activate the ions and restore original mobility, the substrate 11 has to be annealed at an appropriate temperature. By annealing, lattice defects can be repaired, and impurity atoms can also be moved to lattice sites to activate the impurities. Generally, the lattice defects are required to be repaired at approximately 450° C. to 550° C., and the impurities are required to be activated at 900° C. to 1000° C. The activation of the impurities is related to a time and a temperature. If the time takes longer, the temperature is higher, and the impurities are activated more fully. Common annealing methods for the substrate 11 include high-temperature thermal annealing and rapid thermal annealing (RTA). In an example, annealing may be carried out by using a high-temperature thermal annealing process. Specifically, a silicon wafer is heated to 800° C. to 1000° C. by a high temperature furnace, and is kept for 20 min to 40 min. In another example, annealing may be carried out by using an RTA process. Compared with the high-temperature thermal annealing process, the RTA process has a shorter annealing time, which can prevent diffusion of doping ions caused by a long-term high temperature and reduce instantaneous enhanced diffusion of the doping ions.

A structure formed after annealing is shown in FIG. 11D, FIG. 12D, and FIG. 13D.

In an embodiment, the manufacturing method further includes, after S300, the following steps.

At S400, a field oxide layer 17 is formed on the substrate 11.

At S500, a gate 16 is formed on the substrate 11.

At S600, a source region 141, a drain region 142, and a body lead-out region 153 are formed in the substrate 11.

At S700, a dielectric layer 18, a first conductive structure 191, and a second conductive structure 192 are formed on the substrate 11. The first conductive structure 191 extends through the dielectric layer 18 and is electrically connected to the drain region 142. The second conductive structure 192 extends through the dielectric layer 18 and is electrically connected to the source region 141. Further, the second conductive structure 192 is further electrically connected to the body lead-out region 153. In an example, the first conductive structure 191 is a drain electrode, and the second conductive structure 192 is a source electrode.

It should be understood that, although the steps in the flowcharts in the above embodiments are shown in sequence as indicated by the arrows, the steps are not necessarily performed in the order indicated by the arrows. Unless otherwise clearly specified herein, the steps are performed without any strict sequence limitation, and may be performed in other orders. In addition, at least some steps in the above flowcharts may include a plurality of steps or a plurality of stages, and such sub-steps or stages are not necessarily performed at a same moment, and may be performed at different moments. The steps or stages are not necessarily performed in sequence. The steps or stages and other steps or at least some of steps or stages of other steps may be performed in turn or alternately.

In the description of the specification, reference terms such as “some embodiments”, “other embodiments”, and “ideal embodiments” mean that a particular feature, structure, material, or characteristic described in connection with the embodiment or example is included in at least one of the embodiments or examples of the present disclosure. In the specification, the schematic expressions to the above terms are not necessarily referring to the same embodiment or example.

The technical features in the above embodiments may be randomly combined. For concise description, not all possible combinations of the technical features in the above embodiments are described. However, all the combinations of the technical features are to be considered as falling within the scope described in this specification provided that they do not conflict with each other.

The above embodiments only describe several implementations of the present disclosure, and description thereof is specific and detailed, but cannot therefore be understood as a limitation on the patent scope of the present disclosure. It should be noted that those of ordinary skill in the art may further make variants and improvements without departing from the conception of the present disclosure, and these all fall within the protection scope of the present disclosure. Therefore, the patent protection scope of the present disclosure should be subject to the appended claims.

1. A laterally diffused metal oxide semiconductor device, comprising at least one cell structure, the cell structure comprising:
a substrate;
a N-type first well region disposed in the substrate; the first well region being provided with a first region, an isolation region, and a second region that are sequentially arranged in a first direction;
a P-type first doped region and a P-type second doped region, the first doped region being located in the first region, and the second doped region being located in the second region; and
a P-type source region and a P-type drain region disposed in the substrate, wherein the source region is located on a side of the first doped region in a second direction, and the drain region is located on another side of the first doped region in the second direction; the first direction is a width direction of a conductive channel, and the second direction is a length direction of the conductive channel.

2. The laterally diffused metal oxide semiconductor device according to claim 1, wherein a dimension of the source region in the first direction is equal to a dimension of the first doped region in the first direction; and a dimension of the drain region in the first direction is equal to a dimension of the first well region in the first direction.

3. The laterally diffused metal oxide semiconductor device according to claim 2, wherein a ratio of the dimension of the source region in the first direction to the dimension of the first well region in the first direction ranges from 0.3 to 0.5.

4. The laterally diffused metal oxide semiconductor device according to claim 1, wherein the first region comprises a first sub-region and a second sub-region that are arranged in the second direction, the second sub-region being located between the first sub-region and the source region;
wherein doping concentration of N-type impurities in the first sub-region is less than doping concentration of N-type impurities in the second sub-region; and
doping concentration of P-type impurities in the first sub-region is greater than doping concentration of P-type impurities in the second sub-region.

5. The laterally diffused metal oxide semiconductor device according to claim 4, wherein a dimension of the first sub-region in the second direction is greater than a dimension of the second sub-region in the second direction.

6. The laterally diffused metal oxide semiconductor device according to claim 4, wherein a ratio of a dimension of the first sub-region in the second direction to a dimension of the first region in the second direction ranges from 0.6 to 0.8.

7. The laterally diffused metal oxide semiconductor device according to claim 4, wherein a boundary on a side of the first doped region in the first sub-region away from a surface of the substrate is a non-planar surface.

8. The laterally diffused metal oxide semiconductor device according to claim 1, wherein the second region comprises a third sub-region and a fourth sub-region that are arranged in the second direction, the third sub-region being located between the drain region and the fourth sub-region;
wherein doping concentration of N-type impurities in the third sub-region is less than doping concentration of N-type impurities in the fourth sub-region; and
doping concentration of P-type impurities in the third sub-region is greater than doping concentration of P-type impurities in the fourth sub-region.

9. The laterally diffused metal oxide semiconductor device according to claim 8, wherein a dimension of the third sub-region in the second direction is less than a dimension of the fourth sub-region in the second direction.

10. The laterally diffused metal oxide semiconductor device according to claim 9, wherein a ratio of a dimension of the third sub-region in the second direction to a dimension of the second region in the second direction ranges from 0.2 to 0.4.

11. The laterally diffused metal oxide semiconductor device according to claim 9, wherein a boundary on a side of the second doped region in the third sub-region away from a surface of the substrate is a non-planar surface.

12. The laterally diffused metal oxide semiconductor device according to claim 1, wherein the cell structure further comprises:
an N-type body region and a P-type second well region respectively disposed in the substrate and located on two sides of the first doped region in the second direction; the source region being located in the body region, and the drain region being located in the second well region;
an N-type body lead-out region disposed in the body region; and
a gate disposed on the substrate and covering part of the body region.

13. The laterally diffused metal oxide semiconductor device according to claim 12, wherein the laterally diffused metal oxide semiconductor device comprises a plurality of cell structures that are sequentially arranged in the first direction; and
in two adjacent cell structures, first regions of the two cell structures are adjacent to each other, or second regions of the two cell structures are adjacent to each other.

14. The laterally diffused metal oxide semiconductor device according to claim 13, wherein drain regions of the plurality of cell structures are sequentially connected to form an integrated drain region; and
source regions of the two adjacent cell structures are connected to form an integrated source region, and gates of the two adjacent cell structures are connected to form an integrated gate.

15. The laterally diffused metal oxide semiconductor device according to claim 14, further comprising a connection structure electrically connecting two adjacent integrated gates.

16. A manufacturing method for a laterally diffused metal oxide semiconductor device, comprising:
providing a substrate;
forming a N-type first well region, a P-type first doped region, and a P-type second doped region in the substrate; the first well region being provided with a first region, an isolation region, and a second region that are sequentially arranged in a first direction, the first doped region being formed in the first region, and the second doped region being formed in the second region; and
forming a P-type source region in the substrate and on a side of the first doped region in a second direction; and forming a P-type drain region in the substrate and on another side of the first doped region in the second direction; the first direction being a width direction of a conductive channel, and the second direction being a length direction of the conductive channel.

17. The manufacturing method according to claim 16, wherein the substrate has an implanted zone and a non-implanted zone that are adjacent to each other, the implanted zone having a first zone, a second zone, and a third zone that are sequentially arranged in the first direction; the first zone having a first sub-zone and a second sub-zone that are arranged in the second direction, and the third zone having a third sub-zone and a fourth sub-zone that are arranged in the second direction; and
forming the N-type first well region, the P-type first doped region, and the P-type second doped region in the substrate; the first well region being provided with the first region, the isolation region, and the second region that are sequentially arranged in the first direction, the first doped region being formed in the first region, and the second doped region being formed in the second region comprises:
forming a first patterned mask layer on the substrate; the first patterned mask layer comprising a mask portion, a plurality of first mask strips, and a plurality of second mask strips, the mask portion covering the non-implanted zone, the plurality of first mask strips being spaced apart in the first sub-zone along the second direction, and the plurality of second mask strips being spaced apart in the third sub-zone along the second direction;
implanting N-type impurities into the substrate to form the first well region;
removing the first patterned mask layer; and
forming the first doped region and the second doped region in the substrate.
